(19) United States
(12) Patent Application Publication
(10) Pub. No.: US 2025/0188295 A1
(43) Pub. Date: Jun. 12, 2025

(54) MULTILAYER STRUCTURE, EXTERIOR COVER OF ELECTRONIC DEVICE, AND ELECTRONIC DEVICE

(71) Applicant: Samsung Electronics Co., Ltd., Suwon-si (KR)

(72) Inventors: Jungho HWANG, Suwon-si (KR); Jinshik LIM, Suwon-si (KR); Taeyun KIM, Suwon-si (KR); Changmook RIM, Suwon-si (KR); Jinho KIM, Suwon-si (KR); Sungwook CHOI, Suwon-si (KR)

(21) Appl. No.: 19/056,506

(22) Filed: Feb. 18, 2025

Related U.S. Application Data
(63) Continuation of application No. PCT/KR2023/014014, filed on Sep. 18, 2023.

(30) Foreign Application Priority Data
Sep. 30, 2022 (KR) 10-2022-0125695
Oct. 24, 2022 (KR) 10-2022-0137704

(51) Int. Cl. C09D 7/61; H05K 5/03

(52) U.S. Cl. CPC C09D 7/61; H05K 5/03

(57) ABSTRACT

Disclosed herein are a multilayer structure, an exterior cover for an electronic device, and an electronic device including same. The multilayer structure may comprise: a first pigment layer containing TiO₂ and body pigment; a white layer containing TiO₂ on the first pigment layer, and a second pigment layer containing TiO₂ and body pigment on the white layer.

### CROSS-REFERENCE TO RELATED APPLICATIONS

This application is a continuation of International Application No. PCT/KR2023/014014 designating the United States, filed on Sep. 18, 2023, in the Korean Intellectual Property Receiving Office and claiming priority to Korean Patent Application Nos. 10-2022-0125695, filed on Sep. 30, 2022, and 10-2022-0137704, filed on Oct. 24, 2022, in the Korean Intellectual Property Office, the disclosures of each of which are incorporated by reference herein in their entireties.

### BACKGROUND

### Field

The disclosure relates to a multilayer structure, an exterior cover of an electronic device, and an electronic device including the same.

### Description of Related Art

Electronic devices typically refer to devices that perform a specific function according to a loaded program, such as a home appliance, an electronic note, a portable multimedia player, a mobile communication terminal, a tablet personal computer (PC), a video/audio device, a desktop/laptop computer, a vehicle navigation system, and the like. For example, such electronic devices may output stored information as sound or images. As electronic devices have become highly integrated and high-speed and high-volume wireless communication has come into wider use, various functions have been mounted in a single electronic device such as a mobile communication terminal. For example, an entertainment function such as gaming, a multimedia function such as music/video play, a communication and security function for mobile banking, a scheduling function, and an electronic wallet function as well as a communication function have been integrated in a single electronic device.

Electronic devices are being made thin and light for portable purposes. Since electronic devices may be damaged from external physical impact, the electronic devices may be used with an exterior cover (or a case) that covers the exterior of an electronic device. The exterior cover that covers the exterior of an electronic device, not only provides a function of protecting the electronic device, but may also exhibit the effect of showing aesthetic appeal to a user.

### SUMMARY

According to various example embodiments of the present disclosure, a multilayer structure may include: a first pigment layer including TiO₂ and an extender pigment; a white layer including TiO₂ on the first pigment layer; and a second pigment layer including TiO₂ and an extender pigment on the white layer.

According to various example embodiments of the present disclosure, an exterior cover of an electronic device may include: a shielding layer; a multilayer structure layer on the shielding layer; and a base material layer on the multilayer structure layer, wherein the multilayer structure layer may include a first pigment layer including TiO₂ and an extender pigment; a white layer including TiO₂ on the first pigment layer; and a second pigment layer including TiO₂ and an extender pigment on the white layer.

According to various example embodiments of the present disclosure, an electronic device may include the multilayer structure or the exterior cover of the electronic device according to various embodiments of the present disclosure.

### BRIEF DESCRIPTION OF THE DRAWINGS

The above and other aspects, features and advantages of certain embodiments of the present disclosure will be more apparent from the following detailed description, taken in conjunction with the accompanying drawings, in which:

FIG. 1 is a block diagram illustrating an example electronic device in a network environment according to various embodiments;

FIG. 2 is a front perspective view of an electronic device according to various embodiments;

FIG. 3 is a rear perspective view of an electronic device according to various embodiments;

FIG. 4 is an exploded perspective view of an electronic device according to various embodiments;

FIG. 5 is a cross-sectional view taken along line A-A of FIG. 2 and an enlarged view of a portion thereof according to various embodiments;

FIG. 6 is a cross-sectional view illustrating a multilayer structure according to various embodiments;

FIG. 7 is a cross-sectional view illustrating an exterior cover of an electronic device according to various embodiments;

FIG. 8A is a cross-sectional view illustrating an exterior cover of an electronic device according to various embodiments;

FIG. 8B is a cross-sectional view illustrating an exterior cover of an electronic device according to various embodiments;

FIG. 9A is a diagram illustrating various states of a multilayer structure mounted on a front surface of an electronic device, viewed from the front, top, and side according to various embodiments; and

FIG. 9B is a diagram illustrating various states of a multilayer structure or an exterior cover mounted on a rear surface of an electronic device, viewed from the front, top, and side according to various embodiments.

### DETAILED DESCRIPTION

Hereinafter, various example embodiments will be described in greater detail with reference to the accompanying drawings. When describing the various embodiments with reference to the accompanying drawings, like reference numerals refer to like elements and a repeated description related thereto may not be provided.

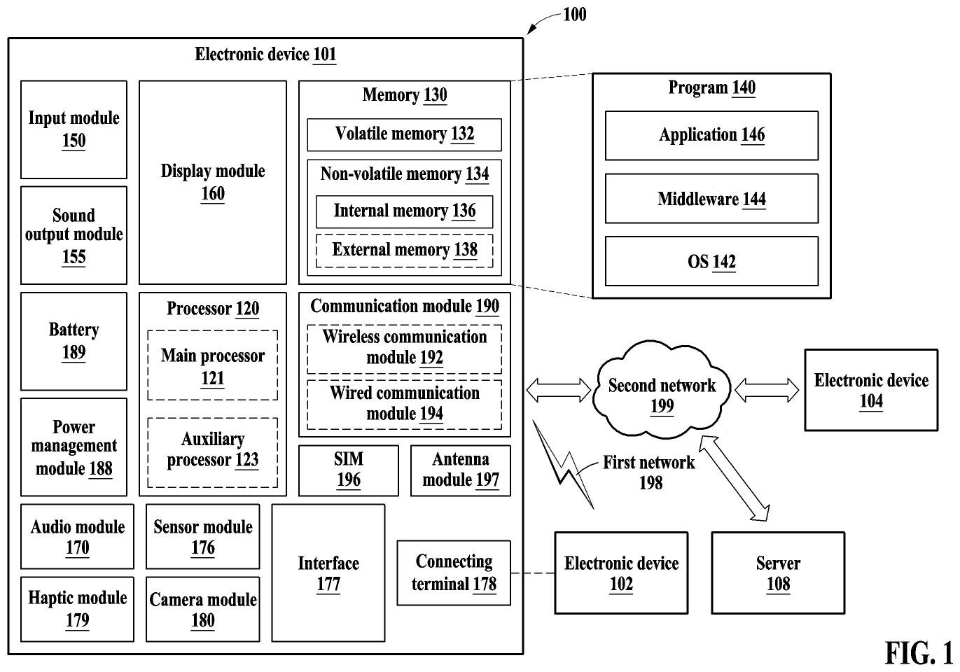

FIG. 1 is a block diagram illustrating an example electronic device 101 in a network environment 100 according to various embodiments.

Referring to FIG. 1, the electronic device 101 in the network environment 100 may communicate with an electronic device 102 via a first network 198 (e.g., a short-range wireless communication network), or communicate with an electronic device 104 or a server 108 via a second network 199 (e.g., a long-range wireless communication network). According to an embodiment, the electronic device 101 may communicate with the electronic device 104 via the server 108. According to an embodiment, the electronic device 101 may include a processor 120, a memory 130, an input module 150, a sound output module 155, a display module 160, an audio module 170, a sensor module 176, an interface 177, a connecting terminal 178, a haptic module 179, a camera module 180, a power management module 188, a battery 189, a communication module 190, a subscriber identification module (SIM) 196, or an antenna module 197. In various embodiments, at least one (e.g., the connecting terminal 178) of the above components may be omitted from the electronic device 101, or one or more other components may be added in the electronic device 101. In various embodiments, some of the components (e.g., the sensor module 176, the camera module 180, or the antenna module 197) may be integrated as a single component (e.g., the display module 160).

The processor 120 may include various processing circuitry and/or multiple processors. For example, as used herein, including the claims, the term “processor” may include various processing circuitry, including at least one processor, wherein one or more of at least one processor, individually and/or collectively in a distributed manner, may be configured to perform various functions described herein. As used herein, when “a processor”, “at least one processor”, and “one or more processors” are described as being configured to perform numerous functions, these terms cover situations, for example and without limitation, in which one processor performs some of recited functions and another processor(s) performs other of recited functions, and also situations in which a single processor may perform all recited functions. Additionally, the at least one processor may include a combination of processors performing various of the recited/disclosed functions, e.g., in a distributed manner. At least one processor may execute program instructions to achieve or perform various functions. The processor 120 may execute, for example, software (e.g., a program 140) to control at least one other component (e.g., a hardware or software component) of the electronic device 101 connected to the processor 120, and may perform various data processing or computation. According to an embodiment, as at least a portion of data processing or computation, the processor 120 may store a command or data received from another component (e.g., the sensor module 176 or the communication module 190) in a volatile memory 132, process the command or the data stored in the volatile memory 132, and store resulting data in a non-volatile memory 134. According to an embodiment, the processor 120 may include a main processor 121 (e.g., a central processing unit (CPU) or an application processor (AP)) or an auxiliary processor 123 (e.g., a graphics processing unit (GPU), a neural processing unit (NPU), an image signal processor (ISP), a sensor hub processor, or a communication processor (CP)) that is operable independently of, or in conjunction with the main processor 121. For example, when the electronic device 101 includes the main processor 121 and the auxiliary processor 123, the auxiliary processor 123 may be adapted to consume less power than the main processor 121 or to be specific to a specified function. The auxiliary processor 123 may be implemented separately from the main processor 121 or as a part of the main processor 121.

The auxiliary processor 123 may control at least some of functions or states related to at least one (e.g., the display module 160, the sensor module 176, or the communication module 190) of the components of the electronic device 101, instead of the main processor 121 while the main processor 121 is in an inactive (e.g., sleep) state or along with the main processor 121 while the main processor 121 is an active state (e.g., executing an application). According to an embodiment, the auxiliary processor 123 (e.g., an ISP or a CP) may be implemented as a portion of another component (e.g., the camera module 180 or the communication module 190) that is functionally related to the auxiliary processor 123. According to an embodiment, the auxiliary processor 123 (e.g., an NPU) may include a hardware structure specified for artificial intelligence (AI) model processing. An AI model may be generated through machine learning. Such learning may be performed by, for example, the electronic device 101 in which AI is performed, or performed via a separate server (e.g., the server 108). Learning algorithms may include, but are not limited to, for example, supervised learning, unsupervised learning, semi-supervised learning, or reinforcement learning. The AI model may include a plurality of artificial neural network layers. An artificial neural network may include, for example, a deep neural network (DNN), a convolutional neural network (CNN), a recurrent neural network (RNN), a restricted Boltzmann machine (RBM), a deep belief network (DBN), and a bidirectional recurrent deep neural network (BRDNN), a deep Q-network, or a combination of two or more thereof, but is not limited thereto. The AI model may additionally or alternatively include a software structure other than the hardware structure.

The memory 130 may store various data used by at least one component (e.g., the processor 120 or the sensor module 176) of the electronic device 101. The various data may include, for example, software (e.g., the program 140) and input data or output data for a command related thereto. The memory 130 may include the volatile memory 132 or the non-volatile memory 134.

The program 140 may be stored as software in the memory 130, and may include, for example, an operating system (OS) 142, middleware 144, or an application 146.

The input module 150 may receive a command or data to be used by another component (e.g., the processor 120) of the electronic device 101, from the outside (e.g., a user) of the electronic device 101. The input module 150 may include, for example, a microphone, a mouse, a keyboard, a key (e.g., a button), or a digital pen (e.g., a stylus pen).

The sound output module 155 may output a sound signal to the outside the electronic device 101. The sound output module 155 may include, for example, a speaker or a receiver. The speaker may be used for general purposes, such as playing multimedia or playing record. The receiver may be used to receive an incoming call. According to an embodiment, the receiver may be implemented separately from the speaker or as a portion of the speaker.

The display module 160 may visually provide information to the outside (e.g., a user) of the electronic device 101. The display module 160 may include, for example, a display, a hologram device, or a projector and control circuitry to control a corresponding one of the display, the hologram device, and the projector. According to an embodiment, the display module 160 may include a touch sensor adapted to sense a touch, or a pressure sensor adapted to measure an intensity of a force incurred by the touch.

The audio module 170 may convert a sound into an electric signal or vice versa. According to an embodiment, the audio module 170 may obtain the sound via the input module 150 or output the sound via the sound output module 155 or an external electronic device (e.g., an electronic device 102 such as a speaker or a headphone) directly or wirelessly connected to the electronic device 101.

The sensor module 176 may detect an operational state (e.g., power or temperature) of the electronic device 101 or an environmental state (e.g., a state of a user) external to the electronic device 101, and generate an electric signal or data value corresponding to the detected state. According to an embodiment, the sensor module 176 may include, for example, a gesture sensor, a gyro sensor, an atmospheric pressure sensor, a magnetic sensor, an acceleration sensor, a grip sensor, a proximity sensor, a color sensor, an infrared (IR) sensor, a biometric sensor, a temperature sensor, a humidity sensor, or an illuminance sensor.

The interface 177 may support one or more specified protocols to be used for the electronic device 101 to be coupled with the external electronic device (e.g., the electronic device 102) directly (e.g., by wire) or wirelessly. According to an embodiment, the interface 177 may include, for example, a high-definition multimedia interface (HDMI), a universal serial bus (USB) interface, a secure digital (SD) card interface, or an audio interface.

The connecting terminal 178 may include a connector via which the electronic device 101 may be physically connected to an external electronic device (e.g., the electronic device 102). According to an embodiment, the connecting terminal 178 may include, for example, an HDMI connector, a USB connector, an SD card connector, or an audio connector (e.g., a headphone connector).

The haptic module 179 may convert an electric signal into a mechanical stimulus (e.g., a vibration or a movement) or an electrical stimulus which may be recognized by a user via his or her tactile sensation or kinesthetic sensation. According to an embodiment, the haptic module 179 may include, for example, a motor, a piezoelectric element, or an electric stimulator.

The camera module 180 may capture a still image and moving images. According to an embodiment, the camera module 180 may include one or more lenses, image sensors, ISPs, or flashes.

The power management module 188 may manage power supplied to the electronic device 101. According to an embodiment, the power management module 188 may be implemented as, for example, at least a part of a power management integrated circuit (PMIC).

The battery 189 may supply power to at least one component of the electronic device 101. According to an embodiment, the battery 189 may include, for example, a primary cell which is not rechargeable, a secondary cell which is rechargeable, or a fuel cell.

The communication module 190 may support establishing a direct (e.g., wired) communication channel or a wireless communication channel between the electronic device 101 and the external electronic device (e.g., the electronic device 102, the electronic device 104, or the server 108) and performing communication via the established communication channel. The communication module 190 may include one or more CPs that are operable independently of the processor 120 (e.g., an AP) and that support a direct (e.g., wired) communication or a wireless communication. According to an embodiment, the communication module 190 may include a wireless communication module 192 (e.g., a cellular communication module, a short-range wireless communication module, or a global navigation satellite system (GNSS) communication module) or a wired communication module 194 (e.g., a local region network (LAN) communication module, or a power line communication (PLC) module). A corresponding one of these communication modules may communicate with the external electronic device 104 via the first network 198 (e.g., a short-range communication network, such as Bluetooth™, wireless-fidelity (Wi-Fi) direct, or infrared data association (IrDA)) or the second network 199 (e.g., a long-range communication network, such as a legacy cellular network, a 5G network, a next-generation communication network, the Internet, or a computer network (e.g., a LAN or a wide area network (WAN))). These various types of communication modules may be implemented as a single component (e.g., a single chip), or may be implemented as multi components (e.g., multiple chips) separate from each other. The wireless communication module 192 may identify and authenticate the electronic device 101 in a communication network, such as the first network 198 or the second network 199, using subscriber information (e.g., international mobile subscriber identity (IMSI)) stored in the SIM 196.

The wireless communication module 192 may support a 5G network after a 4G network, and next-generation communication technology, e.g., new radio (NR) access technology. The NR access technology may support enhanced mobile broadband (eMBB), massive machine type communications (mMTC), or ultra-reliable and low-latency communications (URLLC). The wireless communication module 192 may support a high-frequency band (e.g., a mmWave band) to achieve, e.g., a high data transmission rate. The wireless communication module 192 may support various technologies for securing performance on a high-frequency band, such as, e.g., beamforming, massive multiple-input and multiple-output (massive MIMO), full dimensional MIMO (FD-MIMO), an array antenna, analog beam-forming, or a large scale antenna. The wireless communication module 192 may support various requirements specified in the electronic device 101, an external electronic device (e.g., the electronic device 104), or a network system (e.g., the second network 199). According to an embodiment, the wireless communication module 192 may support a peak data rate (e.g., 20 Gbps or more) for implementing eMBB, loss coverage (e.g., 164 dB or less) for implementing mMTC, or U-plane latency (e.g., 0.5 ms or less for each of downlink (DL) and uplink (UL), or a round trip of 1 ms or less) for implementing URLLC.

The antenna module 197 may transmit or receive a signal or power to or from the outside (e.g., the external electronic device) of the electronic device 101. According to an embodiment, the antenna module 197 may include an antenna including a radiating element including a conductive material or a conductive pattern formed in or on a substrate (e.g., a printed circuit board (PCB)). According to an embodiment, the antenna module 197 may include a plurality of antennas (e.g., array antennas). In such a case, at least one antenna appropriate for a communication scheme used in a communication network, such as the first network 198 or the second network 199, may be selected by, for example, the communication module 190 from the plurality of antennas. The signal or the power may be transmitted or received between the communication module 190 and the external electronic device via the at least one selected antenna. According to an embodiment, another component (e.g., a radio frequency integrated circuit (RFIC)) other than the radiating element may be additionally formed as a portion of the antenna module 197.

According to various embodiments, the antenna module 197 may form a mm Wave antenna module. According to an embodiment, the mm Wave antenna module may include a PCB, an RFIC disposed on a first surface (e.g., a bottom surface) of the PCB or adjacent to the first surface and capable of supporting a designated a high-frequency band (e.g., the mm Wave band), and a plurality of antennas (e.g., array antennas) disposed on a second surface (e.g., a top or a side surface) of the PCB, or adjacent to the second surface and capable of transmitting or receiving signals in the designated high-frequency band.

At least some of the above-described components may be coupled mutually and communicate signals (e.g., commands or data) therebetween via an inter-peripheral communication scheme (e.g., a bus, general purpose input and output (GPIO), serial peripheral interface (SPI), or mobile industry processor interface (MIPI)).

According to an embodiment, commands or data may be transmitted or received between the electronic device 101 and the external electronic device 104 via the server 108 coupled with the second network 199. Each of the external electronic devices 102 and 104 may be a device of the same type as or a different type from the electronic device 101. According to an embodiment, all or some of operations to be executed by the electronic device 101 may be executed at one or more external electronic devices (e.g., the external devices 102 and 104, and the server 108). For example, if the electronic device 101 needs to perform a function or a service automatically, or in response to a request from a user or another device, the electronic device 101, instead of, or in addition to, executing the function or the service, may request the one or more external electronic devices to perform at least part of the function or the service. The one or more external electronic devices receiving the request may perform the at least part of the function or the service requested, or an additional function or an additional service related to the request, and may transfer an outcome of the performing to the electronic device 101. The electronic device 101 may provide the outcome, with or without further processing of the outcome, as at least part of a reply to the request. To that end, a cloud computing, distributed computing, mobile edge computing (MEC), or client-server computing technology may be used, for example. The electronic device 101 may provide ultra low-latency services using, e.g., distributed computing or mobile edge computing. In an embodiment, the external electronic device 104 may include an Internet-of-things (IoT) device. The server 108 may be an intelligent server using machine learning and/or a neural network. According to an embodiment, the external electronic device 104 or the server 108 may be included in the second network 199. The electronic device 101 may be applied to intelligent services (e.g., smart home, smart city, smart car, or healthcare) based on 5G communication technology or IoT-related technology.

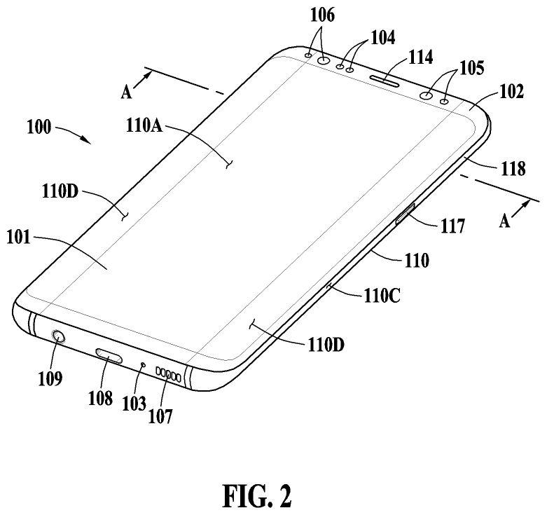

FIG. 2 is a front perspective view of an electronic device according to various embodiments.

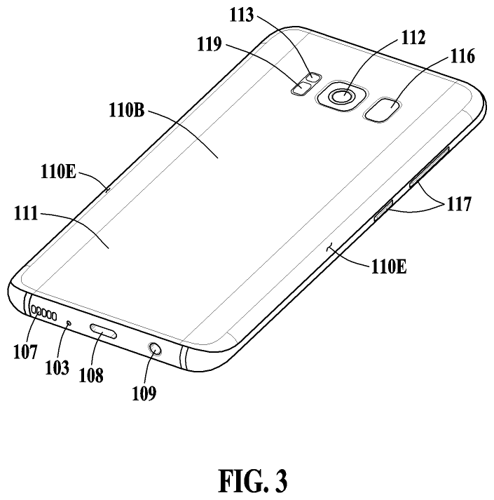

FIG. 3 is a rear perspective view of the electronic device of FIG. 2 according to various embodiments.

Referring to FIGS. 2 and 3, an electronic device 100 according to various embodiments may include a housing 110 including a first surface (or a front surface) 110A, a second surface (or a rear surface) 110B, and a side surface 110C surrounding a space between the first surface 110A and the second surface 110B.

According to an embodiment (not shown), the housing may also refer to a structure which forms a portion of the first surface 110A, the second surface 110B, and the side surface 110C of FIG. 1. According to an embodiment, the first surface 110A may be formed by a front plate 102 (e.g., a glass plate or a polymer plate including various coating layers) of which at least a portion is substantially transparent. The second surface 110B may be formed of a rear plate 111 that is substantially opaque. For example, the rear plate 111 may be formed of coated or colored glass, ceramic, polymer, metal materials (e.g., aluminum, stainless steel (SS), or magnesium) or a combination of at least two of the above materials. The side surface 110C may be coupled to the front plate 102 and the rear plate 111 and may be formed by a side bezel structure (or a “side member”) 118 including a metal and/or a polymer. In an embodiment, the rear plate 111 and the side bezel structure 118 may be integrally formed and may include the same material (e.g., a metal material such as aluminum).

In the illustrated embodiment, the front plate 102 may include two first areas 110D that are curved and extended seamlessly from the first surface 110A toward the rear plate 111 at both ends of a long edge of the front plate 102. In the illustrated embodiment (see FIG. 2), the rear plate 111 may include two second areas 110E that are curved and extended seamlessly from the second surface 110B toward the front plate 102 at both ends of a long edge thereof. In various embodiments, the front plate 102 (or the rear plate 111) may include only one of the first areas 110D (or the second areas 110E). In various embodiments, some of the first areas 110D or the second area 110E may not be included.

According to an embodiment, in a side view of the electronic device 100, the side bezel structure 118 may have a first thickness (or width) at a side in which the first areas 110D or the second areas 110E are not included, and may have a second thickness less than the first thickness at a side in which the first areas 110D or the second areas 110E are included.

In an embodiment, the first areas 110D or the second areas 110E may be formed to be flat instead of being bent, to form a substantially single plane with the first surface 110A or the second surface 110B.

According to an embodiment, the electronic device 100 may include at least one of a display 101, audio modules 103, 107, and 114, sensor modules 104, 116, and 119, camera modules 105, 112, and 113, key input devices 117, a light-emitting element 106, and connector holes 108 and 109. In various embodiments, the electronic device 100 may not include at least one (e.g., the key input devices 117 or the light-emitting element 106) of the components, or may additionally include other components.

According to an embodiment, the display 101 may be visible through, for example, some portions of the front plate 102. In various embodiments, at least a portion of the display 101 may be visible through the first surface 110A and the front plate 102 constructing the first areas 110D of the side surface 110C. In various embodiments, an edge of the display 101 may be formed to be substantially the same as an adjacent outer edge shape of the front plate 102. In an embodiment (not shown), a distance between an outer edge of the display 101 and an outer edge of the front plate 102 may be substantially the same in order to expand a visible area of the display 101.

In an embodiment (not shown), the electronic device 100 may have a recess or an opening formed in a portion of a screen display area of the display 101, and may include at least one of the audio module 114, the sensor module 104, the camera module 105, and the light-emitting device 106 that are aligned with the recess or the opening. In an embodiment (not shown), the electronic device 100 may include, on a rear surface of the screen display area of the display 101, at least one of the audio module 114, the sensor module 104, the camera module 105, the fingerprint sensor 116, and the light-emitting element 106. In an embodiment (not shown), the display 101 may be coupled to or disposed adjacent to a touch sensing circuit, a pressure sensor for measuring an intensity (pressure) of a touch, and/or a digitizer for detecting a magnetic-type stylus pen. In various embodiments, at least a portion of the sensor modules 104 and 119, and/or at least a portion of the key input devices 117 may be disposed in the first areas 110D and/or the second areas 110E.

In an embodiment (not shown), the audio modules 103, 107, and 114 may include a microphone hole 103 and speaker holes 107 and 114. A microphone for acquiring an external sound may be disposed in the microphone hole 103. In various embodiments, a plurality of microphones may be disposed to detect a direction of a sound. The speaker holes 107 and 114 may include an external speaker hole 107, and a receiver hole 114 for a call. In various embodiments, the speaker holes 107 and 114 and the microphone hole 103 may be implemented as a single hole, or a speaker (e.g., a piezo speaker) may be included without the speaker holes 107 and 114.

According to an embodiment, the sensor modules 104, 116, and 119 may generate an electrical signal or a data value corresponding to an internal operating state of the electronic device 100 or an external environmental state. The sensor modules 104, 116, and 119 may include, for example, a first sensor module 104 (e.g., a proximity sensor) and/or a second sensor module (not shown) (e.g., a fingerprint sensor) disposed on the first surface 110A of the housing 110, and/or a third sensor module 119 (e.g., a heart rate monitoring (HRM) sensor) and/or a fourth sensor module 116 (e.g., a fingerprint sensor) disposed on the second surface 110B of the housing 110. The fingerprint sensor may be disposed on both the first surface 110A (e.g., the display 101) and the second surface 110B of the housing 110. According to an embodiment, the electronic device 100 may further include at least one of sensor modules not shown, for example, a gesture sensor, a gyro sensor, an atmospheric pressure sensor, a magnetic sensor, an acceleration sensor, a grip sensor, a color sensor, an infrared (IR) sensor, a biometric sensor, a temperature sensor, a humidity sensor, or an illuminance sensor 104.

According to an embodiment, the camera modules 105, 112, and 113 may include a first camera device 105 disposed on the first surface 110A of the electronic device 100, a second camera device 112 disposed on the second surface 110B, and/or a flash 113. According to an embodiment, the camera devices 105 and 112 may include one or more lenses, an image sensor, and/or an ISP. The flash 113 may include, for example, a light-emitting diode (LED) or a xenon lamp. In various embodiments, two or more lenses (e.g., infrared camera, wide-angle, and telephoto lenses) and image sensors may be disposed on one surface of the electronic device 100.

According to an embodiment, the key input devices 117 may be disposed on the side surface 110C of the housing 110. In an embodiment, the electronic device 100 may not include some or all of the above-described key input devices 117. The key input device 117 that is not included may be implemented in another form such as a soft key on the display 101. In various embodiments, the key input devices may include the sensor module 116 disposed on the second surface 110B of the housing 110.

According to an embodiment, the light-emitting element 106 may be disposed on, for example, the first surface 110A of the housing 110. The light-emitting element 106 may provide, for example, state information of the electronic device 100 in a form of light. In an embodiment, the light-emitting element 106 may provide, for example, a light source that is linked to an operation of the camera module 105. The light-emitting element 106 may include, for example, an LED, an IR LED, and a xenon lamp.

According to an embodiment, the connector holes 108 and 109 may include a first connector hole 108 for accommodating a connector (e.g., a USB connector) for transmitting and receiving power and/or data to and from an external electronic device, and/or a second connector hole 109 (e.g., an earphone jack) for accommodating a connector for transmitting and receiving an audio signal to and from an external electronic device.

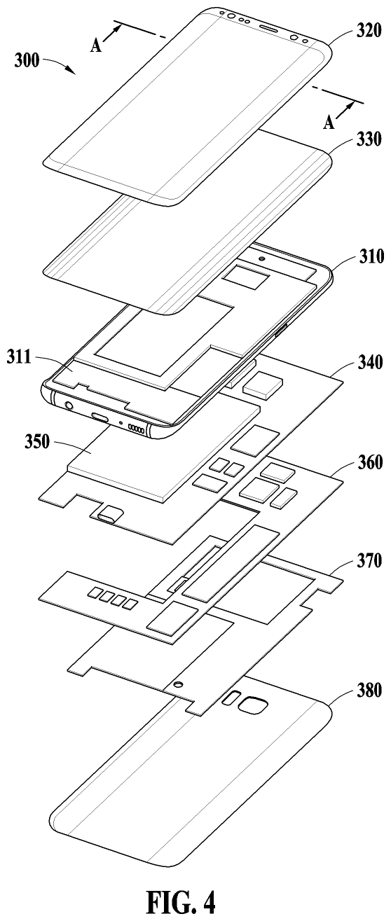

FIG. 4 is an exploded perspective view of an electronic device of FIGS. 2 and 3 according to various embodiments. Referring to FIG. 4, an electronic device 300 may include a side bezel structure 310, a first support member 311 (e.g., a bracket), a front plate 320, a display 330, a printed circuit board (PCB) 340, a battery 350, a second support member 360 (e.g., a rear case), an antenna 370, and a rear plate 380. In various embodiments, the electronic device 300 may omit at least one (e.g., the first support member 311 or the second support member 360) of the components, or may additionally include other components. At least one of the components of the electronic device 300 may be the same as or similar to at least one of the components of the electronic device 100 of FIG. 1 or 2, and a repeated description thereof will be omitted hereinafter.

According to an embodiment, the first support member 311 may be disposed inside the electronic device 300 and connected to the side bezel structure 310, or may be formed integrally with the side bezel structure 310. The first support member 311 may be formed of, for example, a metal material and/or a non-metal material (e.g., polymer). The display 330 may be coupled to one surface of the first support member 311, and the PCB 340 may be coupled to another surface of the first support member 311.

According to an embodiment, the PCB 340 may be provided with a processor, a memory, and/or an interface mounted thereon. The processor may include, for example, one or more of a CPU, an AP, a GPU, an ISP, a sensor hub processor, and a CP. The memory may include, for example, a volatile memory or a non-volatile memory. The interface may include, for example, an HDMI, a USB interface, an SD card interface, and/or an audio interface. For example, the interface may electrically or physically connect the electronic device 300 to an external electronic device, and may include a USB connector, an SD card/multimedia card (MMC) connector, or an audio connector.

According to an embodiment, the battery 350, which is a device for supplying power to at least one component of the electronic device 300, may include, for example, a primary cell that is not rechargeable, a secondary cell that is rechargeable, or a fuel cell. For example, at least a portion of the battery 350 may be disposed on substantially the same plane as the PCB 340. The battery 350 may be disposed integrally inside the electronic device 300, or disposed detachably from the electronic device 300.

According to an embodiment, the antenna 370 may be disposed between the rear plate 380 and the battery 350. The antenna 370 may include, for example, a near field communication (NFC) antenna, a wireless charging antenna, and/or a magnetic secure transmission (MST) antenna. The antenna 370 may perform short-range communication with an external device, or may wirelessly transmit and receive power required for charging to and from the external device.

In an embodiment, an antenna structure may be formed by a portion of the side bezel structure 310 and/or the first support member 311 or a combination thereof.

The electronic device 100 according to various embodiments of the present disclosure may include an electronic device such as a bar type, a foldable type, a rollable type, a slidable type, a wearable type, and a tablet personal computer (PC) and/or a notebook PC.

The electronic device 100 according to various embodiments of the present disclosure is not limited to the above-described example, and may include various other electronic devices.

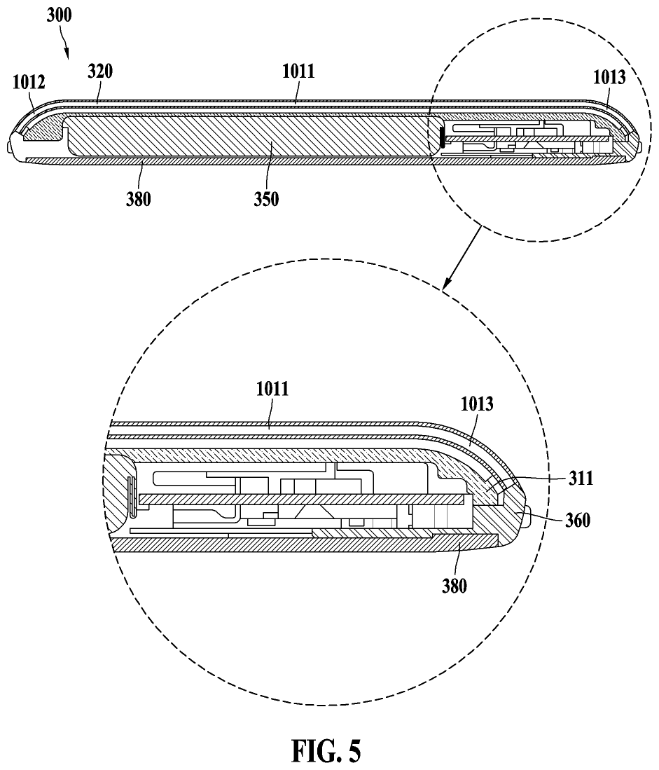

FIG. 5 is a cross-sectional view taken along line A-A of FIG. 2 and an enlarged view of a portion thereof according to various embodiments.

Referring to FIG. 5, the electronic device 300 (e.g., the electronic device 300 of FIG. 4) may have the first support member 311 (e.g., a bracket) fixed to the housing to support a substrate and a display. The display 330 may be fixed to a front surface of the first support member 311 (e.g., a bracket), and the front plate 320 may be disposed on an upper portion thereof. On a front surface of the electronic device 300 (e.g., the front surface 110A of FIG. 2), the front plate 320 may be fixed by being attached to the first support member 311 (e.g., a bracket) by a first adhesive member. The front plate 320 may be fixed by being attached to the first support member 311 (e.g., a bracket) by the first adhesive member corresponding to a shape at the end of the housing. The front plate 320 may be formed into a shape with a uniform thickness and a certain curvature. In an embodiment, the front plate 320 may include a flat portion 1011 and left and right curved portions 1012 and 1013, all of which may be formed with a uniform thickness.

According to an embodiment, the rear plate 380 mounted on the rear surface (e.g., the rear surface 110B of FIG. 2) of the electronic device 300 may also be fixed to the housing by a second adhesive member. The rear plate 380 may be formed in a shape in which the thickness becomes thinner toward the left and right edges (e.g., a shape formed in a 2.5 dimensional manner). It may include the battery 350 and the second support member 360 (e.g., a rear case). The rear plate 380 may have a flat surface.

According to an embodiment, the rear plate 380 may be attached to the second support member 360 (e.g., a rear case). The second support member 360 (e.g., a rear case) may have one surface having a similar curvature to the rear plate 380, and at least a portion of the one surface may additionally include an adhesive layer. The adhesive layer may be attached by fixing the rear plate 380 to the second support member 360 (e.g., a rear case). According to an embodiment, the rear plate 380 may further include an antenna module (not shown) on the rear surface. For example, the antenna module may be an NFC, a wireless charging antenna, a MST antenna. The rear plate 380 may further include through holes (not shown) for assembling peripheral components such as a camera, a HRM sensor, a flash, or the like.

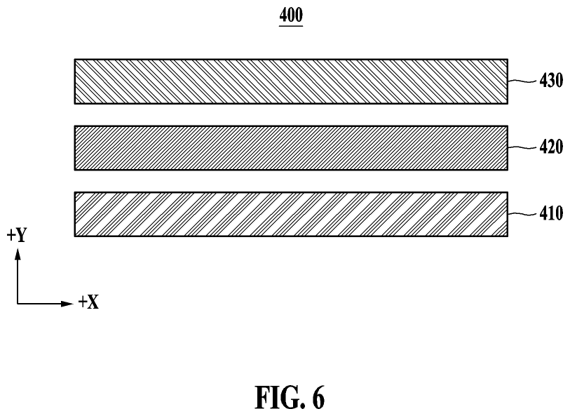

FIG. 6 is a cross-sectional view illustrating a multilayer structure 400 according to various embodiments.

According to an embodiment, FIG. 6 may be a cross-sectional view of the multilayer structure 400 applied to an electronic device (e.g., the front plate 102 and the rear plate 111 of the electronic device 100 of FIGS. 2 and 3) or (e.g., the front plate 320 and the rear plate 380 of the electronic device 300 of FIGS. 4 and 5).

According to an embodiment, the multilayer structure 400 in FIG. 6 may include a first pigment layer 410, a white layer 420, and a second pigment layer 430.

According to an embodiment, the first pigment layer 410 may include TiO₂ and an extender pigment. According to an embodiment, the first pigment layer 410 may be applied onto at least a portion of an exterior portion of an electronic device (e.g., the front plate 102 and the rear plate 111 of the electronic device 100 of FIGS. 2 and 3) or (e.g., the front plate 320 of the electronic device 300 of FIGS. 4 and 5), or a colored layer (e.g., a shielding layer) of a component (e.g., an exterior cover) of the electronic device.

According to an embodiment, TiO₂ in the first pigment layer 410 is a white pigment, and a TiO₂ content in the first pigment layer 410 may be about 10 wt % to about 40 wt %. In various embodiments, the TiO₂ content in the first pigment layer 410 may be lower than a TiO₂ content included in the white layer 420, the second pigment layer 430, or both. In various embodiments, the TiO₂ content in the first pigment layer 410 may be a first content selected from about 40 wt % or less; about less than 40 wt %; about 35 wt % or less; about 20 wt % to about 35 wt %; about 25 wt % to about 35 wt %; or about 25 wt % to about 30 wt %. In various embodiments, the first pigment layer 410 may improve the adhesion of the multilayer structure 400 while providing a whiteness function by applying the first content.

According to an embodiment, the TiO₂ in the first pigment layer 410 may have a particle size of about 100 nm (nanometers) to about 50 μm (micrometers); about 100 nm to about 30 μm; about 100 nm to about 20 μm; about 1 μm to about 10 μm; or about 4 μm to about 8 μm. For example, a particle size may represent a diameter, a radius, a length, a thickness, or the like depending on the shape of the particle. For example, the particle size of TiO₂ of the first pigment layer 410 may be the same as or different from that of the white layer 420 or the second pigment layer 430.

According to an embodiment, in the first pigment layer 410, the extender pigment may be combined with the white pigment, TiO₂ to implement a white color, thereby strengthening hiding power and implementing a shielding effect. For example, the extender pigment may control the amount of light that is transmitted through a colored layer (e.g., a lower layer) (e.g., a shielding layer). For example, a shielding effect for a dark color (e.g., a black or gray color) (e.g., a color of the shielding layer) may be implemented while maintaining the white color of the first pigment layer 410.

According to an embodiment, a content of the extender pigment in the first pigment layer 410 may be about 10 wt % to about 50 wt %. In various embodiments, the content of the extender pigment in the first pigment layer 410 may be more than a content of the extender pigment included in the second pigment layer 430. In various embodiments, the content of the extender pigment in the first pigment layer 410 may be a second content selected from about 10 wt % or more; about more than 10 wt %; about 15 wt % to about 40 wt %; about 20 wt % to about 40 wt %; about 25 wt % to about 40 wt %; about 25 wt % to about 35 wt %; or about 30 wt % to about 40 wt %. In various embodiments, the first pigment layer 410 may improve a whiteness by increasing the proportion of the extender pigment by applying the second content. For example, a dark color (e.g., black or gray) or light that is transmitted or reflected from the colored layer (e.g., the lower layer) (e.g., the shielding layer) may be shielded or offset to maintain the whiteness.

According to an embodiment, the extender pigment in the first pigment layer 410 may be lactate, silicate, oxide, hydroxide, carbonate, halogen salt, or the like including at least one or a combination of Ba, Ca, Al, Si, or Mg. For example, the extender pigment may be a non-colored extender pigment. For example, the extender pigment may include, but is not limited to, at least one or more of titanium dioxide, antimony oxide, zinc oxide, barium carbonate, calcium carbonate, aluminum silicate, silica (SiO₂), a silicic acid compound (e.g., silicic acid), magnesium carbonate, a magnesium salt (e.g., magnesium silicate, magnesium silicate hydroxide, or magnesium chloride), talc, barium sulfate, aluminum oxide, aluminum hydroxide, or kaolin (white clay, clay), or a combination thereof. In various embodiments, the extender pigment in the first pigment layer 410 may be selected to implement the whiteness and increase the shielding property of projected light or color by considering the light reflectance and combination of TiO₂. In various embodiments, the extender pigment in the first pigment layer 410 may include magnesium silicate, magnesium silicate hydroxide, or magnesium chloride.

According to an embodiment, the extender pigment in the first pigment layer 410 may include a particle size of about 100 nm to about 50 μm; about 100 nm to about 30 μm; about 100 nm to about 20 μm; about 1 μm to about 10 μm; or about 4 μm to about 8 μm. For example, the particle size may represent a diameter, a radius, a length, a thickness, or the like depending on the shape of the particle.

According to an embodiment, a thickness of the first pigment layer 410 may be about 0.5 μm to about 150 μm; about 0.5 μm to about 100 μm; about 1 μm to about 50 μm; about 1 μm to about 40 μm; about 1 μm to about 30 μm; about 1 μm to about 20 μm; about 1 μm to about 15 μm; about 1 μm to about 10 μm; about 5 μm to about 30 μm; about 5 μm to about 20 μm; about 5 μm to about 10 μm; or about 10 μm to about 20 μm. The thickness range described in various embodiments may be applied to improve a diffuse reflection function or the adhesion. In addition, it may prevent and/or reduce a dark color (e.g., black or gray) of the colored layer (e.g., the shielding layer) from being projected.

According to an embodiment, the white layer 420 may include a white pigment, TiO₂. According to an embodiment, the white layer 420 may be included between the first pigment layer 410 and the second pigment layer 430. This may form a sandwich structure of the white layer 420, the first pigment layer 410, and the second pigment layer 430 to prevent and/or reduce peeling of the white layer 420 including a large TiO₂ content, thereby improving the adhesion of the multilayer structure 400. In some examples, the white layer 420 may be formed on the first pigment layer 410 (e.g., on the surface), and the second pigment layer 430 may be formed on the white layer 420 (e.g., on the surface).

According to an embodiment, the TiO₂ content in the white layer 420 may be about 40 wt % to about 70 wt %. In various embodiments, the TiO₂ content in the white layer 420 may be more than the TiO₂ content in the first pigment layer 410, the second pigment layer 430, or both. In various embodiments, the white layer 420 may be a base structural layer for maintaining the whiteness by including a higher content of TiO₂ than the first pigment layer 410 or the second pigment layer 430. In various embodiments, the TiO₂ content in the first pigment layer 410 may be a third content selected from about 40 wt % or more; about 50 wt % or more; about 40 wt % to about 70 wt %; about 55 wt % to about 70 wt %; or about 60 wt % to about 70 wt %. In various embodiments, the first pigment layer 410 may improve the whiteness by applying the third content. In various embodiments, the multilayer structure 400 may form a sandwich structure in which the white layer 420 containing a high content of TiO₂ is positioned between the first pigment layer 410 and the second pigment layer 430 containing a relatively low content of TiO₂, thereby implementing the adhesion improved by the first pigment layer 410 and the second pigment layer 430 while maintaining the whiteness by the white layer 420 having a high content of TiO₂.

According to an embodiment, the TiO₂ in the white layer 420 may have a particle size of about 100 nm to about 50 μm; about 100 nm to about 30 μm; about 100 nm to about 20 μm; about 1 μm to about 10 μm; or about 4 μm to about 8 μm. For example, the particle size may represent a diameter, a radius, a length, a thickness, or the like depending on the shape of the particle. For example, the particle size of the TiO₂ of the white layer 420 may be the same as or different from that of the first pigment layer 410 or the second pigment layer 430.

According to an embodiment, a thickness of the white layer 420 may be about 0.5 μm to about 150 μm; about 0.5 μm to about 100 μm; about 1 μm to about 50 μm; about 1 μm to about 40 μm; about 1 μm to about 30 μm; about 1 μm to about 20 μm; about 1 μm to about 15 μm; about 1 μm to about 10 μm; about 5 μm to about 30 μm; about 5 μm to about 20 μm; about 5 μm to about 10 μm; about 10 μm to about 40 μm; about 10 μm to about 30 μm, or about 10 μm to about 20 μm. In various embodiments, the thickness of the white layer 420 may be thicker than that of the first pigment layer 410, the second pigment layer 430, or both. In various embodiments, the white layer 420 may improve the hiding power to implement the whiteness by applying the thickness range described above.

According to an embodiment, the second pigment layer 430 may include TiO₂ and an extender pigment. According to an embodiment, the second pigment layer 430 may be formed on the white layer 420 (e.g., on the surface).

According to an embodiment, the TiO₂ in the second pigment layer 430 is a white pigment, and the TiO₂ content in the second pigment layer 430 may be about 30 wt % to about 50 wt %. In various embodiments, the TiO₂ content in the second pigment layer 430 may be higher than the TiO₂ content in the first pigment layer 410. In various embodiments, the TiO₂ content in the second pigment layer 430 may be a fourth content selected from about more than 30 wt %; about 35 wt % or more; about 35 wt % to about 50 wt %; or about 40 wt % to about 50 wt %. In various embodiments, the second pigment layer 430 may improve the adhesion of the multilayer structure 400 while implementing the whiteness by applying the fourth content.

According to an embodiment, the TiO₂ in the second pigment layer 430 may have a particle size of about 100 nm to about 50 μm; about 100 nm to about 30 μm; about 100 nm to about 20 μm; about 1 μm to about 10 μm; or about 4 μm to about 8 μm. For example, the particle size may represent a diameter, a radius, a length, a thickness, or the like depending on the shape of the particle. For example, the particle size of the TiO₂ in the second pigment layer 430 may be the same as or different from that of the white layer 420 or the first pigment layer 410.

In an embodiment, a content of the extender pigment in the second pigment layer 430 may be about 5 wt % to about 30 wt %. In various embodiments, the content of the extender pigment in the second pigment layer 430 may be lower than the content of the extender pigment included in the first pigment layer 410. In various embodiments, the content of the extender pigment in the second pigment layer 430 may be a fifth content selected from about 20 wt % or less; about 15 wt % or less; about 5 wt % to about 15 wt %; about 10 wt % to about 15 wt %; or about 5 wt % to about 10 wt %. In various embodiments, the second pigment layer 430 may reduce the proportion of the extender pigment, reduce the hiding power, and reflect the whiteness realized in the white layer 420 by applying the fifth content.

According to an embodiment, the extender pigment in the second pigment layer 430 may include lactate, silicate, oxide, hydroxide, carbonate, halogen salt, or the like including at least one or a combination of Ba, Ca, Al, Si, or Mg. For example, the extender pigment may be a non-colored extender pigment. For example, the extender pigment may include, but is not limited to, at least one or more of titanium dioxide, antimony oxide, zinc oxide, barium carbonate, calcium carbonate (e.g., lime), aluminum silicate, silica (SiO₂), a silicic acid-based compound (e.g., silicic acid), magnesium carbonate, a magnesium salt (e.g., magnesium silicate, magnesium silicate hydroxide, or magnesium chloride), talc, barium sulfate, aluminum oxide, aluminum hydroxide, or kaolin (white clay, clay), or a combination thereof. In various embodiments, the extender pigment of the second pigment layer 430 may include an extender pigment having a reflectance lower than that of TiO₂, and may include, for example, at least one or more of talc, calcium carbonate (e.g., lime), aluminum oxide (Al₂O₃), or a silicic acid-based compound (e.g., silicic acid), or a combination thereof.

According to an embodiment, the extender pigment in the second pigment layer 430 may have a particle size of about 100 nm to about 50 μm; about 100 nm to about 30 μm; about 100 nm to about 20 μm; about 1 μm to about 10 μm; or about 4 μm to about 8 μm. For example, the particle size may represent a diameter, a radius, a length, a thickness, or the like depending on the shape of the particle. In various embodiments, the particle size of the extender pigment in the second pigment layer 430 may be the same as or different from that of the first pigment layer 410.

According to an embodiment, the second pigment layer 430 may further include a colored pigment. In various embodiments, the colored dye may improve the whiteness of the multilayer structure 400 by reflecting the whiteness reflectance of the white layer 420 by the high content of TiO₂ while reducing the hiding power between the extender pigments. In various embodiments, the second pigment layer 430 may express a color by a colored pigment while maintaining the whiteness by the white layer 420.

According to an embodiment, the colored dye in the second pigment layer 430 may be about 0.1 wt % to about 10 wt %. In various embodiments, the color may be expressed while maintaining the whiteness projected from the lower layer (e.g., the white layer 420) within the content range of the colored dye described herein.

According to an embodiment, the colored pigment may include an inorganic coloring pigment, an organic coloring pigment, or both. For example, the inorganic coloring pigment may include, but is not limited to, at least one or more or a combination of red iron oxide (e.g., Fe₂O₃), bright red oxide (e.g., Pb₃O₄), cadmium red (e.g., CdS+CdSe), manganese violet (e.g., NH₄MnP₂O₇), Prussian blue (e.g., Fe(NH₄)Fe(CN)₆×H₂O), ultramarine (e.g., Na₆₋₈Al₆Si₆O₂₄S₂₋₄), cobalt blue (e.g., CoO·Al₂O₃), chrome green (e.g., lead chromate+blue), emerald green (e.g., Cu(CH₃CO₂)₂·3Cu(AsO₂)₂)), lead chromate (e.g., PbCrO₄), yellow iron oxide (e.g., FeO(OH) or Fe₂O₃·H₂O), cadmium yellow (e.g., CdS or CdS+ZnS), titanium yellow (e.g., TiO₂·NiO·Sb₂O₃), chrome orange (e.g., PbCrO₄·PbO), molybdenum orange (e.g., PbCrO₄·PbMoO₄·PbSO₄), white lead, or zinc oxide.

For example, the organic coloring pigment may include, but is not limited to, at least one or more of an anthraquinone pigment, an azo pigment, an anilino azo pigment, a triphenylmethane pigment, a pyrazole azo-based pigment, a pyridine azo-based pigment, an atrapyridone pigment, an oxonol pigment, a benzylid pigment, a xanthene pigment, a phthalocyanine pigment, a thioindigo pigment, a perinone pigment, a perylene pigment, or a quinacridone pigment, or a combination thereof.

According to an embodiment, a thickness of the second pigment layer 430 may be about 0.5 μm to about 150 μm; about 0.5 μm to about 100 μm; about 1 μm to about 50 μm; about 1 μm to about 40 μm; about 1 μm to about 30 μm; about 1 μm to about 20 μm; about 1 μm to about 10 μm; about 1 μm to about 5 μm; about 5 μm to about 30 μm; about 5 μm to about 20 μm; about 5 μm to about 15 μm; about 5 μm to about 10 μm; or about 10 μm to about 20 μm. In various embodiments, the thickness of the second pigment layer 430 may be thinner than that of the first pigment layer 410 or the white layer 420. In various embodiments, the whiteness projected from the white layer 420 may be maintained and the adhesion may be improved by applying the thickness range described herein.

According to an embodiment, the first pigment layer 410, the white layer 420, and the second pigment layer 430 may each further include a base resin such as a curable (e.g., a thermosetting resin or a photocurable resin) resin, a transparent resin, or the like, if necessary. For example, it may include, but is not limited to, resins such as an acrylonitrile butadiene styrene (ABS) copolymer resin, a polyurethane-based resin, an acrylate-based resin, a urethane acrylate-based resin, a (meth)acrylate-based resin, a silicone acrylate-based resin, an epoxy acrylate-based resin, an epoxy-based resin (e.g., a bisphenol A type epoxy resin, a cresol novolac type epoxy resin, a phenol novolac type epoxy resin, and a multifunctional epoxy resin); or a silicone-based resin, or a transparent resin, or the like.

According to an embodiment, the first pigment layer 410, the white layer 420, and the second pigment layer 430 may each be a single layer or multiple layers. In various embodiments, the multiple layers may have each layer including the same or different compositions. In various embodiments, the multiple layers may include a number of layers of about 2 or more; about 4 or more; or about 2 to about 10.

According to an embodiment, the multilayer structure 400 may have a light transmittance of about 1% or less; about 0.1% or less; or about 0.01% or less. In various embodiments, the multilayer structure 400 may have a black color transmittance of about 0.01% or less. In various embodiments, the multilayer structure 400 may have a light shielding ratio of about 99.7% or more. According to an embodiment, the multilayer structure 400 may have a whiteness (lightness) of L95 or higher (e.g., a wavelength range of about 400 nm to about 700 nm in a visible light region). In various embodiments, the multilayer structure 400 may be utilized as a base material (e.g., an exterior decoration material) that implements a whiteness while minimizing/reducing the effect or having almost no effect on the color or light of the projected colored layer (e.g., shielding layer) and enables expression or decoration (e.g., a pattern) of various colors for implementing aesthetic effects.

According to an embodiment, a cured structure (e.g., the multilayer structure 400) was manufactured by performing baking (e.g., at about 50° C. to about 100° C.) after performing a lamination process by a continuous printing process with a printing ink according to a configuration of Table 1 shown below. For example, the cured structure has a low boiling point solvent in a quick-drying form and a urea reaction cured structure with a room temperature cured structure.

According to an embodiment, Table 1 shows components and a layer composition of each layer, a reflectance, and a lightness (L) value (a means for determining brightness and whiteness) of the multilayer structure 400. In Table 1, it may be confirmed that a whiteness of an L value (lightness, CIE L*) of 96 or more is implemented. For example, the multilayer structure 400 may maintain the whiteness regardless of the presence or absence of a color for the shielding layer (e.g., gray color), and may maintain the whiteness while shielding 99.7% or more of light.

TABLE 1

| No | | 1 | 2 | 3 | 4 | 5 |
|---|---|---|---|---|---|---|
| TiO₂ 45% + | | 1 | 1 | 1 | 1 (Red tin) | 1 (Blue tin) |
| extender 10% | | | | | | |
| TiO₂ 60% | | 4 | 4 | 4 | 4 | 4 |
| TiO₂ 30% + | | 0 | 1 | 3 | 1 | 1 |
| extender 30% | | | | | | |
| Shielding (Grey) | | 1 | 1 | 1 | 1 | 1 |
| Total number of | | 6 | 7 | 9 | 7 | 7 |
| printed colors | | | | | | |
| Expected | | 42 | 54 | 66 | 54 | 54 |
| thickness (μm) | | | | | | |
| Reflectance (740 | | 85.55 | 88.01 | 89.45 | 88.14 | 87.46 |
| nm) | | | | | | |
| Whiteness | L | 95.88 | 96.43 | 96.76 | 96.3 | 96.27 |
| (color) | a | −1.27 | −1.17 | −1.11 | −0.86 | −1.63 |
| | b | 0.46 | 0.91 | 1.19 | 0.73 | 0.52 |

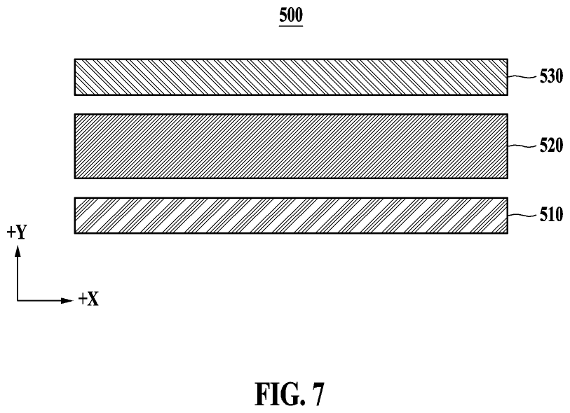

FIG. 7 is a cross-sectional view illustrating an exterior cover 500 of an electronic device according to various embodiments.

According to an embodiment, FIG. 7 may be a cross-sectional view of an exterior cover 500 applied to an electronic device (e.g., the rear plate 111 of the electronic device 100 of FIGS. 2 and 3) or (e.g., the rear plate 380 of the electronic device 300 of FIGS. 4 and 5).

According to an embodiment, the exterior cover 500 in FIG. 7 may include a base material layer 530, a multilayer structure layer 520, and a shielding layer 510.

According to an embodiment, the base material layer 530 is an outermost layer of the exterior cover 500, and may include a layer for implementing a function (e.g., an aesthetic function or a protective function) required by an electronic device (e.g., the electronic device 100 of FIGS. 1 to 3 and the electronic device 300 of FIGS. 4 and 5).

According to an embodiment, the base material layer 530 may include, but is not limited to, a coating layer or a printed layer, a film, a thin film, a foil, or a sheet including at least one or a combination of an organic material (e.g., a resin, polymer, or plastic), an inorganic material (e.g., oxide or ceramic), a metallic material (e.g., a metal, alloy, or intermetallic compound), or an organic-inorganic composite material.

According to an embodiment, the base material layer 530 may include a single layer or multiple layers. According to an embodiment, a thickness of the base material layer 530 may be about 0.5 μm to about 150 μm, which may be a thickness of each layer or the entire base material layer 530.

According to an embodiment, the base material layer 530 may be formed of, but is not limited to, an acrylonitrile butadiene styrene-based (ABS) copolymer resin, a polyurethane-based resin, an acrylate-based resin, a urethane acrylate-based resin, a (meth)acrylate-based resin, a silicone acrylate-based resin, an epoxy acrylate-based resin, or an epoxy-based resin (e.g., a bisphenol A type epoxy resin, a cresol novolac type epoxy resin, a phenol novolac type epoxy resin, and a multifunctional epoxy resin); a resin such as a silicone-based resin; a transparent resin, glass, oxide such as ZrO₂, SiO₂, Al₂O₃; a silane-based compound; a siloxane-based compound, aluminum, stainless steel (STS), magnesium, a magnesium alloy (e.g., a Mg—Al—Z-based alloy), and the like.

For example, the transparent resin may include, but is not limited to, at least one or more of polyester, polyethylene, polyethylene terephthalate (PET), polypropylene, polydimethylsiloxane (PDMS), poly-4-vinylphenol, polymethyl methacrylate, polyvinylidene fluoride, polystyrene, polycarbonate, polyimide (PI), cellulose, polyvinyl chloride, polytetrafluoroethylene, polyvinyl alcohol, and/or polyurethane (e.g., TPU), or a combination thereof.

According to an embodiment, the base material layer 530 may include at least one or more of a transparent layer, a translucent layer, or an opaque layer, or a combination thereof. For example, it may include a transparent film layer or a transparent adhesive layer.

According to an embodiment, the base material layer 530 may include an adhesive layer (not shown), a primer layer (not shown), or a surface modification layer (not shown). For example, the adhesive layer, the primer layer, or the surface modification layer may each include at least one or more of an optical clear adhesive (OCA), an optical clear resin (OCR), a pressure sensitive adhesive (PSA), an epoxy-based adhesive, a silicone-based adhesive, an acrylic adhesive, and/or a urethane-based adhesive, or a combination thereof, but is not limited thereto. For example, the adhesive layer may be a transparent adhesive layer. For example, the adhesive layer, the primer layer, or the surface modification layer may each include at least one or more of the organic material (e.g., the resin, polymer, or plastic), the inorganic material (e.g., the oxide or ceramic), the metallic material (e.g., the metal, alloy, or intermetallic compound), or the organic-inorganic composite material described above for the base material layer 530, or a combination thereof.

According to an embodiment, the multilayer structure layer 520 may include a multilayer structure (e.g., the multilayer structure 400 of FIG. 6) according to various embodiments of the present disclosure. According to an embodiment, the multilayer structure (e.g., the multilayer structure 400 of FIG. 6) has a sandwich structure in which a white layer (e.g., the white layer 420 of FIG. 5) containing a high content of TiO₂ is positioned between a first pigment layer (e.g., the first pigment layer 410 of FIG. 6) and a second pigment layer (e.g., the second pigment layer 430 of FIG. 6) containing relatively low TiO₂, so that the first pigment layer and the second pigment layer may implement excellent adhesion to the base material layer 530 and the shielding layer 510 that are in contact with each other, respectively. According to an embodiment, a multilayer structure (e.g., the multilayer structure 400 of FIG. 6) may be used to improve hiding power to implement the whiteness with little influence on the color projected from the shielding layer 510, and to express color or decorative effects.

According to an embodiment, the shielding layer 510 may include at least one or more of a dark-colored (e.g., gray or black) inorganic material, organic material, or metallic material having a light shielding function, or a combination thereof. In various embodiments, the shielding layer may be a coating layer, a printed layer, or a film. In various embodiments, a thickness of the shielding layer 510 may be about 0.5 μm to about 10 μm.

According to an embodiment, the shielding layer 510 may have a light transmittance of about 1% or less; about 0.1% or less; or about 0.01% or less. In various embodiments, the multilayer structure 520 may have a light transmittance of about 1% or less; about 0.1% or less; or about 0.01% or less. In various embodiments, the multilayer structure 520 may have a black color transmittance of about 0.01% or less. In various embodiments, the shielding layer 510 may have a light shielding ratio of about 99.7% or more. In various embodiments, the multilayer structure 520 may have a light shielding ratio of about 99.7% or more.

According to an embodiment, the multilayer structure 520 may have a whiteness (lightness) of L95 or more (e.g., a wavelength range of about 400 nm to about 700 nm in the visible light region). In various embodiments, the multilayer structure 520 may be utilized as a base material (e.g., an exterior decoration material) that implements a whiteness while minimizing/reducing the effect or having almost no effect on the color or light of the projected colored layer (e.g., the shielding layer 510) and enables expression or decoration (e.g., a pattern) of various colors for implementing aesthetic effects.

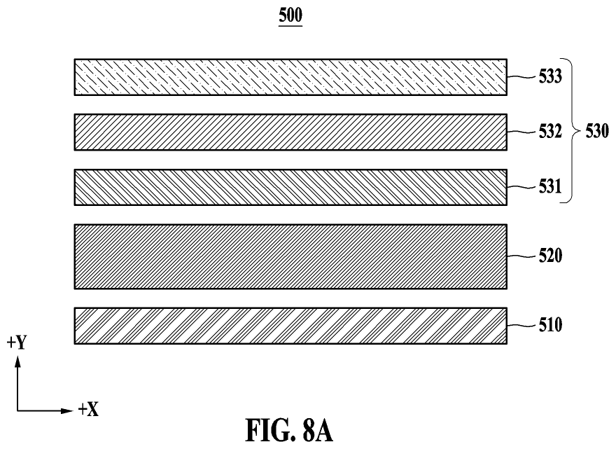

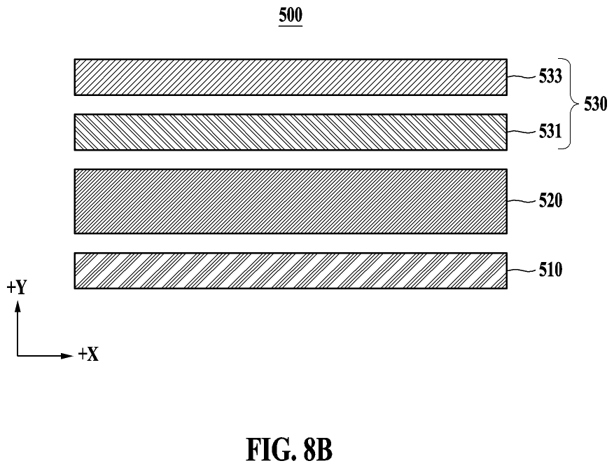

According to an embodiment, FIGS. 8A and 8B are cross-sectional views illustrating the exterior cover 500 of FIG. 7 according to various embodiments. FIGS. 8A and 8B are cross-sectional views of the exterior cover 500 applied to an electronic device (e.g., the rear plate 111 of the electronic device 100 of FIGS. 2 and 3) or (e.g., the rear plate 380 of the electronic device 300 of FIGS. 4 and 5).

According to an embodiment, the exterior cover 500 in FIG. 8A may include the base material layer 530, the multilayer structure layer 520, and the shielding layer 510, and the base material layer 530 may include a film layer 531, a transparent adhesive layer 532, and a high-hardness layer 533. In various embodiments, the film layer 531 may have a thickness of about 75 μm to about 125 μm, and each of the transparent adhesive layer 532 and the high-hardness layer 533 may have a thickness of about 10 μm to about 20 μm, respectively. In various examples, the high-hardness layer 533 may be a coating film, a film, a sheet, a thin film, a foil, or a sheet containing plastic, a metal, glass, or a hard coating.

According to an embodiment, the exterior cover 500 in FIG. 8B may include the base material layer 530, the multilayer structure layer 520, and the shielding layer 510, and the base material layer 530 may include a transparent resin layer 531 and the high-hardness layer 533. In various embodiments, the transparent resin layer 531 may have a thickness of about 1 μm to about 5 μm, and the high-hardness layer 533 may have a thickness of about 10 μm to about 20 μm. In various embodiments, the transparent resin layer 531 may be a thin film pretreatment layer for an acrylate-based resin for adhesion. In various embodiments, the transparent resin layer 531 may contain a silane-based compound or a silane-based resin for adhesion. In various embodiments, the high-hardness layer 533 may be a coating film, a film, a thin film, a foil, or a sheet containing plastic, a metal, glass, or a hard coating. In various embodiments, the high-hardness layer 533 may contain glass, plastic, or a metal.

According to an embodiment, an exterior cover (e.g., the exterior cover 500 of FIG. 7) may be provided by the following manufacturing process.

According to an embodiment, a manufacturing process of the exterior cover may include a step of forming a base material layer (e.g., the base material layer 530 of FIG. 7); a step of forming a multilayer structure layer (e.g., the multilayer structure layer 520 of FIG. 7) (e.g., the multilayer structure 400 of FIG. 6); and a step of forming a shielding layer (e.g., the shielding layer 510 of FIG. 7). In various embodiments, the process may include a step of forming a base material layer; a step of forming a multilayer structure layer on the base material layer; and a step of forming a shielding layer on the multilayer structure layer.

According to an embodiment, the step of forming the base material layer includes forming a functional layer that may be used as an outermost layer of an exterior cover (e.g., the exterior cover 500 of FIG. 7), and steps such as coating, printing, adhesion, deposition, and bonding may be used.

According to an embodiment, the step of forming the multilayer structure layer (e.g., the multilayer structure layer 520 of FIG. 7) (e.g., the multilayer structure 400 of FIG. 6) may include a step of forming a first pigment layer (e.g., the first pigment layer 410 of FIG. 6); a step of forming a white layer (e.g., the white layer 420 of FIG. 6); and a step of forming a second pigment layer (e.g., the second pigment layer 430 of FIG. 6). In various embodiments, the process may include a step of forming a first pigment layer, a step of forming a white layer on the first pigment layer, and a step of forming a second pigment layer on the white layer. In various embodiments, the process may include a step of forming a second pigment layer, a step of forming a white layer on the second pigment layer, and a step of forming a first pigment layer on the white layer. In various embodiments, the multilayer structure layer may be printed or bonded directly onto a base material portion. In various embodiments, the multilayer structure layer may be printed or bonded directly onto the shielding layer. In various embodiments, an additional base material (e.g., a sacrificial substrate) (e.g., a release film) may be utilized for coating or printing the multilayer structure layer.

According to an embodiment, the step of forming the multilayer structure layer may utilize a coating step or a printing step. According to an embodiment, the step of forming the multilayer structure layer may include a curing step. In various embodiments, the curing step may be performed after forming the first pigment layer, the second pigment layer, and the second pigment layer in a sequential operation. In various embodiments, the curing process may include thermal curing, photocuring, or both, and, if necessary, an appropriate curing agent or curing catalyst may be further added according to the curing step. For example, the thermal curing may be performed by baking at a temperature of about 50° C. to about 100° C.; about 60° C. to about 80° C.; or about 65° C. to about 75° C. for a process time of about 1 minute or more; about 10 minutes or more; about 30 minutes or more; about 1 hour or more, or about 2 hours or more. For example, the photocuring may be performed at a light dose of about 10 mJ/cm² to about 1000 mJ/cm² (e.g., a wavelength of about 400 nm or less) for a process time of about 1 minute or more; about 10 minutes or more; about 30 minutes or more; about 1 hour or more, or about 2 hours or more. Minimum and maximum process times may be selected from the process times described herein.

According to an embodiment, in the step of forming the shielding layer (e.g., the shielding layer 510 of FIG. 7), a shielding layer may be formed on the multilayer structure layer (e.g., the multilayer structure layer 520 of FIG. 7) (e.g., the multilayer structure 400 of FIG. 6) by a coating step or a printing step. In various embodiments, in the step of forming the shielding layer, the shielding layer may be formed on the first pigment layer (e.g., the first pigment layer 410 of FIG. 6) or the first pigment layer (e.g., the first pigment layer 410 of FIG. 6) may be bonded to the shielding layer.

According to an embodiment, the step of forming the shielding layer may include a curing step. In various embodiments, the curing step may include thermal curing, photocuring, or both, and, if necessary, an additional curing agent or curing catalyst may be further added according to the curing step. For example, the thermal curing may be performed by baking at a temperature of about 50° C. to about 100° C.; about 60° C. to about 80° C.; or about 65° C. to about 75° C. for a process time of about 1 minute or more; about 10 minutes or more; about 30 minutes or more; about 1 hour or more, or about 2 hours or more. For example, the photocuring may be performed at a light dose of about 10 mJ/cm² to about 1000 mJ/cm² (e.g., a wavelength of about 400 nm or less) for a process time of about 1 minute or more; about 10 minutes or more; about 30 minutes or more; about 1 hour or more, or about 2 hours or more. Minimum and maximum process times may be selected from the process times described herein.

In an embodiment, the “printing” herein may include, but is not limited to, pad printing, screen printing, gravure printing, or the like.

According to an embodiment, the “coating” herein may include, but is not limited to, spin coating, spray coating, flow coating, bar coating, die coating, slot coating, blade coating, knife coating, reverse coating, transfer roll coating, gravure roll coating, cast coating, slot orifice coating, calendar coating, or the like.

According to an embodiment, an ink composition may be used in the “printing” step and the “coating” step herein, and, for example, the ink composition may be selected as a solvent having appropriate components and contents for the step, which is not specifically mentioned herein.

According to various embodiments, a multilayer structure (e.g., the multilayer structure 400 of FIG. 6) or an exterior cover (e.g., the exterior cover 500 of FIGS. 7, 8A, and 8B) may be disposed on a front surface, a rear surface, or each of front and rear surfaces of the electronic device.

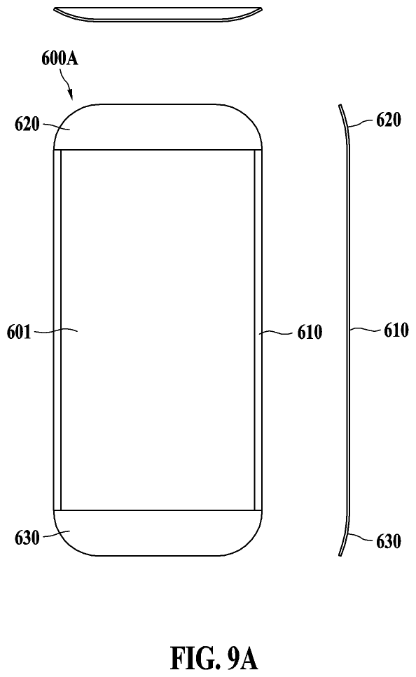

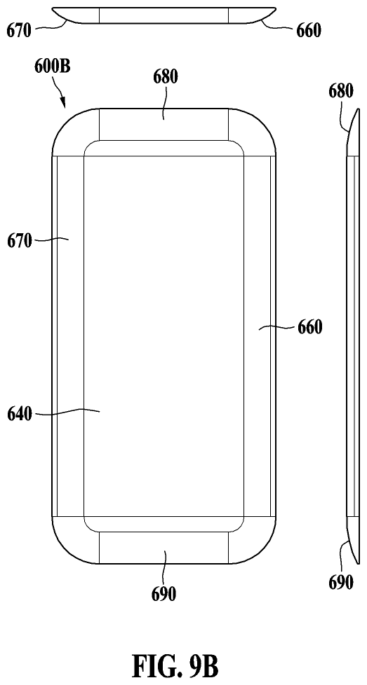

For example, FIG. 9A is a diagram illustrating various states of a multilayer structure mounted on a front surface of an electronic device, viewed from the front, top, and side according to various embodiments of the present disclosure.

According to an embodiment, the multilayer structure (e.g., the multilayer structure 400 of FIG. 6) in FIG. 9A may be mounted on a bezel printing lines 610, 620, and 630 of a display window 601 of a front plate 600A of an electronic device (e.g., the front plate 102 of the electronic device 100 of FIGS. 2 and 3) or (e.g., the front plate 320 of the electronic device 300 of FIGS. 4 and 5) to implement a white color (e.g., pure white).

According to an embodiment, the front plate 600A may include a flat bezel area 610 and a curved portion, in which an upper bezel area 620 on an upper side of the flat bezel area 610 and a lower bezel area 630 on a lower side of the flat bezel area 610 are bent, based on the display area 601. A multilayer structure (e.g., the multilayer structure 400 of FIG. 6) with a shape corresponding thereto may be disposed.

For example, FIG. 9B is a diagram illustrating various states of a multilayer structure or an exterior cover mounted on a rear surface of an electronic device, viewed from the front, top, and side according to various embodiments of the present disclosure.

According to an embodiment, an exterior cover (e.g., the exterior cover 500 of FIG. 7) in FIG. 9B may be mounted on a rear plate 600B of the electronic device (e.g., the rear plate 111 of the electronic device 100 of FIGS. 2 and 3) or (e.g., the rear plate 380 of the electronic device 300 of FIGS. 4 and 5).

According to an embodiment, the rear plate 600B may include a flat portion 640, and a left area 660, a right area 670, an upper area 680, and a lower area 690 which are each curved. An exterior cover (e.g., the exterior cover 500 of FIG. 7) with a shape corresponding thereto may be disposed.

Various embodiments of the present disclosure may relate to a multilayer structure (e.g., the multilayer structure 400 of FIG. 6) including a white pigment, and an exterior cover (e.g., the exterior cover 500 of FIG. 7) of an electronic device including the multilayer structure of the present disclosure. In addition, various embodiments of the present disclosure may relate to an electronic device (e.g., the electronic device 100 of FIGS. 2 and 3) or (e.g., the electronic device 300 of FIGS. 4 and 5) including the multilayer structure and the exterior cover of the present disclosure.

The exterior cover may be made by applying an ink to a material such as plastic (e.g., transparent plastic), glass, or a film using pad printing, screen printing, or the like to manufacture a decorative exterior with a color. The ink used at this time is applied once or several times to manufacture a printed surface with desired hiding power. In the printing process, repeated printing layers are stacked to obtain the hiding power, however, in a case of a white (e.g., TiO₂) layer, it is difficult to secure the hiding power for the white color alone. When the white layer has insufficient hiding power, a plurality of colored layers (e.g., shielding layers) may be configured (e.g., rear configuration) or a dark colored shielding layer may be configured. However, due to insufficient shielding power of the white layer in the multilayer structure, the color of the shielding layer may be projected and the whiteness may decrease.

Therefore, according to various embodiments, the multilayer structure may provide a material (or a component) that implements aesthetic (e.g., color expression or color pattern) and functional performance suitable (or required) for the exterior of the electronic device, which may improve the hiding power of the white pigment and thus enhance whiteness. However, the purpose of the present disclosure is not limited to the contents described above.

According to an example embodiment, a multilayer structure (e.g., the multilayer structure 400 of FIG. 6) may include: a first pigment layer including TiO₂ and an extender pigment; a white layer including TiO₂ on the first pigment layer; and a second pigment layer including TiO₂ and an extender pigment on the white layer.

According to an example embodiment, the first pigment layer, the white layer, and the second pigment layer may include laminated structural layers formed by a coating step or a printing step.

According to an example embodiment, a TiO₂ content in the white layer may be higher than a TiO₂ content in the first pigment layer, the second pigment layer, or both. According to various example embodiments, the TiO₂ content in the white layer may be higher than the TiO₂ content in the first pigment layer and the second pigment layer.

According to an example embodiment, the TiO₂ content of the second pigment layer may be higher than the TiO₂ content of the first pigment layer.

According to an example embodiment, the TiO₂ content in the first pigment layer may be in a range of 10 wt % to 40 wt %. According to various example embodiments, the TiO₂ content in the first pigment layer may be in a range of 25 wt % to about 35 wt %.

According to an example embodiment, the TiO₂ content of the second pigment layer may be in a range of about 30 wt % to about 50 wt %. According to various example embodiments, the TiO₂ content of the second pigment layer may be in a range of about 40 wt % to about 50 wt %.

According to an example embodiment, the TiO₂ content in the white layer may be in a range of about 40 wt % to about 70 wt %. According to various example embodiments, the TiO₂ content in the white layer 420 may be in a range of about 60 wt % to about 70 wt %.

According to an example embodiment, a content of the extender pigment in the first pigment layer may be greater than a content of the extender pigment in the second pigment layer.

According to an example embodiment, the content of the extender pigment in the first pigment layer may be in a range of 10 wt % to 50 wt %. According to various example embodiments, the content of the extender pigment in the first pigment layer may be in a range of 30 wt % to 40 wt %.

According to an example embodiment, the content of the extender pigment in the second pigment layer may be in a range of 5 wt % to 30 wt %. According to various example embodiments, the content of the extender pigment in the second pigment layer may be in a range of 5 wt % to 10 wt %.

According to an example embodiment, a thickness of the second pigment layer may be less than a thickness of the first pigment layer or the white layer.

According to an example embodiment, each of the thicknesses of the first pigment layer, the second pigment layer, and the white layer may be in a range of 0.5 μm to 150 μm.

According to an example embodiment, the second pigment layer may further include a colored dye. According to an example embodiment, the second pigment layer may further include a colored dye including an inorganic dye, an organic dye, or both.

According to an example embodiment, a content of the colored dye in the second pigment layer 430 may be in a range of about 0.1 wt % to about 10 wt %.

According to an example embodiment, an exterior cover (e.g., the exterior cover 500 of FIG. 7, 8A, or 8B) of an electronic device may include a shielding layer; a multilayer structure layer on the shielding layer; and a base material layer on the multilayer structure layer, and the multilayer structure layer may include a first pigment layer including TiO₂ and an extender pigment; a white layer including TiO₂ on the first pigment layer; and a second pigment layer including TiO₂ and an extender pigment on the white layer.

According to an example embodiment, the multilayer structure layer in the exterior cover of the electronic device may include the multilayer structure (e.g., the multilayer structure 400 of FIG. 6) according to various example embodiments of the present disclosure.

According to an example embodiment, the base material layer may include a single layer or multiple layers including at least one or a combination of a polymer, glass, or a metal.

According to an example embodiment, the base material layer may include a single layer or multiple layers including at least one or more or a combination of a coating layer (e.g., a printed layer), a film, or a thin film.

According to an example embodiment, the base material layer may include an adhesive layer, a primer layer, or a surface modification layer.

According to an example embodiment, the base material layer may include at least one or more or a combination of a transparent layer, a translucent layer, or an opaque layer.

According to an example embodiment, the base material layer may have a thickness in a range of about 0.5 μm to about 150 μm.

According to an example embodiment, the shielding layer may have a thickness in a range of about 0.5 μm to about 10 μm.

According to an example embodiment, an electronic device (e.g., the electronic device 100 of FIGS. 2 and 3 or e.g., the electronic device 300 of FIGS. 4 and 5) may include a multilayer structure (e.g., the multilayer structure 400 of FIG. 6) or an exterior cover (e.g., the exterior cover 500 of FIG. 7, 8A, or 8B) according to various embodiments of the present disclosure.

According to an example embodiment, a multilayer structure (e.g., the multilayer structure 400 of FIG. 6) or an exterior cover (e.g., the exterior cover 500 of FIG. 7, 8A, or 8B) may be included in at least a portion of the exterior of the electronic device.

According to an example embodiment, the electronic device may include a multilayer structure (e.g., the multilayer structure 400 of FIG. 6) or an exterior cover (e.g., the exterior cover 500 of FIG. 7, 8A, or 8B) on a front surface or a rear surface.

According to an example embodiment, the electronic device may include a multilayer structure (e.g., the multilayer structure 400 of FIG. 6) in a bezel area of a display window of a front plate.

According to an example embodiment, the electronic device may be a mobile electronic device.

According to an example embodiment, the electronic device may be a portable electronic device.

The electronic device according to various example embodiments disclosed herein may be one of various types of electronic devices. The electronic device may include, for example, a portable communication device (e.g., a smartphone), a computer device, a portable multimedia device, a portable medical device, a camera, a wearable device, a home appliance device, or the like. According to an embodiment of the disclosure, the electronic device is not limited to those described above.

It should be appreciated that various embodiments of the disclosure and the terms used therein are not intended to limit the technological features set forth herein to particular embodiments and include various changes, equivalents, or replacements for a corresponding embodiment. In connection with the description of the drawings, like reference numerals may be used for similar or related components. It is to be understood that a singular form of a noun corresponding to an item may include one or more of the things, unless the relevant context clearly indicates otherwise. As used herein, “A or B,” “at least one of A and B,” “at least one of A or B,” “A, B or C,” “at least one of A, B and C,” and “at least one of A, B, or C,” each of which may include any one of the items listed together in the corresponding one of the phrases, or all possible combinations thereof. Terms, such as “first” or “second”, are simply used to distinguish a component from another component and do not limit the components in other aspects (e.g., importance or sequence). It is to be understood that if an element (e.g., a first element) is referred to, with or without the term “operatively” or “communicatively”, as “coupled with,” “coupled to,” “connected with,” or “connected to” another element (e.g., a second element), the element may be coupled with the other element directly (e.g., by wire), wirelessly, or via a third element.

As used in connection with various embodiments of the disclosure, the term “module” may include a unit implemented in hardware, software, or firmware, or any combination thereof, and may interchangeably be used with other terms, for example, “logic,” “logic block,” “part,” or “circuitry”. A module may be a single integral component, or a minimum unit or part thereof, adapted to perform one or more functions. For example, according to an embodiment, the module may be implemented in a form of an application-specific integrated circuit (ASIC).

According to various embodiments, each component (e.g., a module or a program) of the above-described components may include a single entity or multiple entities, and some of the multiple entities may be separately disposed in different components. According to various embodiments, one or more of the above-described components or operations may be omitted, or one or more other components or operations may be added. Alternatively or additionally, a plurality of components (e.g., modules or programs) may be integrated into a single component. In such a case, the integrated component may still perform one or more functions of each of the plurality of components in the same or similar manner as they are performed by a corresponding one of the plurality of components before the integration. According to various embodiments, operations performed by the module, the program, or another component may be carried out sequentially, in parallel, repeatedly, or heuristically, or one or more of the operations may be executed in a different order or omitted, or one or more other operations may be added.

While the disclosure has been illustrated and described with reference to various example embodiments, it will be understood that the various example embodiments are intended to be illustrative, not limiting. It will be further understood by those skilled in the art that various changes in form and detail may be made without departing from the true spirit and full scope of the disclosure, including the appended claims and their equivalents. It will also be understood that any of the embodiment(s) described herein may be used in conjunction with any other embodiment(s) described herein.

What is claimed is:

1. A multilayer structure comprising:
a first pigment layer comprising TiO₂ and an extender pigment;
a white layer comprising TiO₂ on the first pigment layer; and
a second pigment layer comprising TiO₂ and an extender pigment on the white layer.

2. The multilayer structure of claim 1, wherein a TiO₂ content in the white layer is higher than a TiO₂ content in the first pigment layer, the second pigment layer, or both.

3. The multilayer structure of claim 1, wherein the TiO₂ content of the second pigment layer is higher than the TiO₂ content of the first pigment layer.

4. The multilayer structure of claim 1, wherein
the TiO₂ content in the first pigment layer is in a range of 10 wt % to 40 wt %, or
the TiO₂ content of the second pigment layer is in a range of 30 wt % to 50 wt %.

5. The multilayer structure of claim 1, wherein the TiO₂ content in the white layer is in a range of 40 wt % to 70 wt %.

6. The multilayer structure of claim 1, wherein a content of the extender pigment in the first pigment layer is higher than a content of the extender pigment in the second pigment layer.

7. The multilayer structure of claim 1, wherein
the content of the extender pigment in the first pigment layer is in a range of 10 wt % to 50 wt %, or
the content of the extender pigment in the second pigment layer is in a range of 5 wt % to 30 wt %.

8. The multilayer structure of claim 1, wherein a thickness of the second pigment layer is less than a thickness of the first pigment layer or a thickness of the white layer.

9. The multilayer structure of claim 1, wherein each of the thicknesses of the first pigment layer, the second pigment layer, and the white layer is in a range of 0.5 micrometers (μm) to 150 μm.

10. The multilayer structure of claim 1, wherein the second pigment layer further comprises a colored dye.

11. The multilayer structure of claim 1, wherein a content of the colored dye in the second pigment layer is in a range of 0.1 wt % to 10 wt %.

12. An exterior cover of an electronic device comprising:
a shielding layer;
a multilayer structure layer on the shielding layer; and
a base material layer on the multilayer structure layer,
wherein the multilayer structure layer comprises:
a first pigment layer comprising TiO₂ and an extender pigment;
a white layer comprising TiO₂ on the first pigment layer; and
a second pigment layer comprising TiO₂ and an extender pigment on the white layer.

13. The exterior cover of claim 12, wherein the multilayer structure layer comprises:
a first pigment layer comprising TiO₂ and an extender pigment;
a white layer comprising TiO₂ on the first pigment layer; and
a second pigment layer comprising TiO₂ and an extender pigment on the white layer.

14. An electronic device comprising the multilayer structure of claim 11.

15. The electronic device of claim 14, comprising:
the multilayer structure on a bezel of a front surface, or
the exterior cover on a rear surface.
